(19) United States
(12) Patent Application Publication
(10) Pub. No.: US 2012/0217502 A1
(43) Pub. Date: Aug. 30, 2012

(54) DISPLAY DEVICE AND MANUFACTURING METHOD OF THE SAME

(75) Inventor: Isao SUZUMURA, Tokyo (JP)

(73) Assignee: Hitachi Displays, Ltd.

(21) Appl. No.: 13/404,043

(22) Filed: Feb. 24, 2012

(30) Foreign Application Priority Data
Feb. 28, 2011 (JP) 2011-042849

(51) Int. Cl. H01L 29/786; H01L 21/336

(52) U.S. Cl. 257/72; 438/158; 257/E29.273; 257/E21.409

(57) ABSTRACT

Provided is a display device which includes: a gate electrode; a first semiconductor layer in a crystallized state which is formed over the gate electrode; a source electrode and a drain electrode which are formed over the first semiconductor layer; and a second semiconductor layer which extends from a side of the first semiconductor layer and is interposed between one of the source electrode and the drain electrode and the first semiconductor layer, wherein the second semiconductor layer includes a first portion which is formed in a crystallized state and brought into contact with the first semiconductor layer, and a second portion which has lower crystallinity than the first portion.

### CROSS-REFERENCE TO RELATED APPLICATION

The present application claims priority from Japanese application JP2011-042849 filed on Feb. 28, 2011, the content of which is hereby incorporated by reference into this application.

### BACKGROUND OF THE INVENTION

1. Field of the Invention

The present invention relates to a display device and a manufacturing method of the display device.

2. Description of the Related Art

There has been known a case where a crystalline semiconductor layer is used as a channel layer of a thin film transistor (TFT) used in a display device such as a liquid crystal display device or an organic EL display device.

According to JP 2010-135502 A, a semiconductor element which decreases an OFF current while ensuring an ON current is disclosed. In JP 2010-135502 A, there is the description that an active layer, in a Raman spectrum, has a first microcrystalline silicon layer in which a ratio between peak area strength ascribed to SiH and peak area strength ascribed to SiH₂ is 2 or more.

### SUMMARY OF THE INVENTION

When a crystalline semiconductor layer is used as a channel layer of a thin film transistor in place of an amorphous semiconductor layer, electrical mobility and an ON current are increased in terms of performances of the thin film transistor. However, when a crystalline semiconductor layer is used as such a channel layer, an OFF current at the time of applying a high electric field to a drain region is liable to be increased compared to the case where the amorphous semiconductor layer is used as the channel layer.

The present invention has been made in view of such a drawback, and it is an object of the present invention to provide a display device having a thin film transistor capable of decreasing an OFF current while ensuring an ON current and a manufacturing method of the display device.

To overcome the above-mentioned drawback, according to one aspect of the present invention, there is provided a display device which includes: a gate electrode; a first semiconductor layer in a crystallized state which is formed over the gate electrode; a source electrode and a drain electrode which are formed over the first semiconductor layer; and a second semiconductor layer which extends from a side of the first semiconductor layer and is interposed between one of the source electrode and the drain electrode and the first semiconductor layer, wherein the second semiconductor layer includes a first portion which is formed in a crystallized state by being brought into contact with the first semiconductor layer and a second portion which has lower crystallinity than the first portion.

According to one mode of the display device of the present invention, an insulation layer may be formed between the gate electrode and the first semiconductor layer, the first portion of the second semiconductor layer may be formed over the first semiconductor layer, and the second portion of the second semiconductor layer may be formed over the insulation layer.

According to another mode of the display device of the present invention, the display device may further include a side-wall oxide film which is formed over a side wall of the first semiconductor layer.

According to another mode of the display device of the present invention, the first portion of the second semiconductor layer may be formed thicker than the second portion of the second semiconductor layer.

According to another mode of the display device of the present invention, the display device may further include a third semiconductor layer doped with an impurity which is formed over the second semiconductor layer.

According to another mode of the display device of the present invention, the second semiconductor layer may be doped with an impurity.

According to another mode of the display device of the present invention, an upper surface of the first semiconductor layer may be doped with an impurity, and the second semiconductor layer may have the higher impurity concentration than the upper surface of the first semiconductor layer.

According to another mode of the display device of the present invention, the second semiconductor layer may contain germanium.

According to another mode of the display device of the present invention, the second semiconductor layer may contain carbon.

To overcome the above-mentioned drawback, according to another aspect of the present invention, there is provided a method of manufacturing a display device which includes: a gate electrode; a first semiconductor layer in a crystallized state which is formed over the gate electrode; a source electrode and a drain electrode which are formed over the first semiconductor layer; and a second semiconductor layer which extends from a side of the first semiconductor layer and is interposed between one of the source electrode and the drain electrode and the first semiconductor layer, the method including a step of:

forming the second semiconductor layer as a film by setting a ratio of a flow rate of a raw material gas with respect to a flow rate of a carrier gas to 1/10 or less (preferably, 1/100 or less) thus forming a first portion which is crystallized by being brought into contact with the first semiconductor layer and a second portion having lower crystallinity than the first portion in the second semiconductor layer.

According to the present invention, it is possible to provide a display device having a thin film transistor capable of decreasing an OFF current while ensuring an ON current and a manufacturing method of the display device.

### BRIEF DESCRIPTION OF THE DRAWINGS

FIG. 1 is an equivalent circuit diagram of a thin film transistor substrate of a liquid crystal display device according to a first embodiment of the present invention;

FIG. 2 is an enlarged plan view showing a pixel region of the thin film transistor substrate according to the first embodiment;

FIG. 3 is a view showing a cross section taken along a line III-III in FIG. 2;

FIG. 4 is a graph showing a characteristic between a gate voltage and a drain current of a thin film transistor according to the first embodiment;

FIG. 5 is a view showing the energy band structure on a side of a first semiconductor layer when a strong electric field is applied to a drain electrode and a gate electrode in the thin film transistor of the first embodiment;

FIG. 6A is a view showing the manner of manufacturing the thin film transistor of the first embodiment;

FIG. 6B is a view showing the manner of manufacturing the thin film transistor of the first embodiment;

FIG. 6C is a view showing the manner of manufacturing the thin film transistor of the first embodiment;

FIG. 6D is a view showing the manner of manufacturing the thin film transistor of the first embodiment;

FIG. 6E is a view showing the manner of manufacturing the thin film transistor of the first embodiment;

FIG. 6F is a view showing the manner of manufacturing the thin film transistor of the first embodiment;

FIG. 7 is a cross-sectional view of a thin film transistor according to a second embodiment;

FIG. 8 is a graph showing the relationship between a film forming time and a film thickness under a film forming condition of the second embodiment;

FIG. 9 is an enlarged plan view showing a pixel region of a thin film transistor substrate according to a third embodiment;

FIG. 10 is a view showing a cross section taken along a line X-X in FIG. 9;

FIG. 11A is a view showing the manner of manufacturing the thin film transistor of the third embodiment;

FIG. 11B is a view showing the manner of manufacturing the thin film transistor of the third embodiment;

FIG. 11C is a view showing the manner of manufacturing the thin film transistor of the third embodiment;

FIG. 11D is a view showing the manner of manufacturing the thin film transistor of the third embodiment;

FIG. 11E is a view showing the manner of manufacturing the thin film transistor of the third embodiment;

FIG. 12 is a view showing a cross section of a thin film transistor of a display device according to a fourth embodiment;

FIG. 13 is a view showing a cross section of a thin film transistor of a display device according to a fifth embodiment;

FIG. 14 is a view showing a cross section of a thin film transistor of a display device according to a sixth embodiment;

FIG. 15 is a graph showing the relationship between a film forming time and a film thickness under a film forming condition in the sixth embodiment; and

FIG. 16 is a view showing the energy band structure on a side of a first semiconductor layer when a strong electric field is applied to a drain electrode and a gate electrode in a thin film transistor of a seventh embodiment.

### DETAILED DESCRIPTION OF THE INVENTION

Hereinafter, embodiments of the present invention are explained in conjunction with drawings.

### First Embodiment

A display device according to a first embodiment of the present invention is an IPS (In-plane Switching) type liquid crystal display device. The liquid crystal display device includes a thin film transistor substrate on which scanning signal lines, video signal lines, thin film transistors, pixel electrodes and counter electrodes are arranged, a counter substrate which faces the thin film transistor substrate in an opposed manner and forms color filters thereon, and a liquid crystal material which is sealed in a region sandwiched between both substrates.

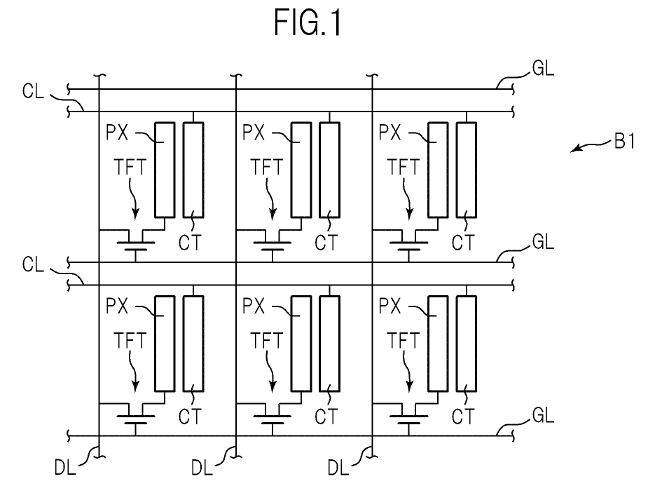

FIG. 1 is an equivalent circuit diagram of the thin film transistor substrate B1 of the liquid crystal display device. As shown in FIG. 1, on the thin film transistor substrate B1, a large number of scanning signal lines GL extend in the lateral direction in the drawing at equal intervals, and a large number of video signal lines DL extend in the vertical direction in the drawing at equal intervals. Respective pixel regions which are arranged in a matrix array are defined by the scanning signal lines GL and the video signal lines DL. Further, common signal lines CL extend in the lateral direction in the drawing parallel to the respective scanning signal lines GL.

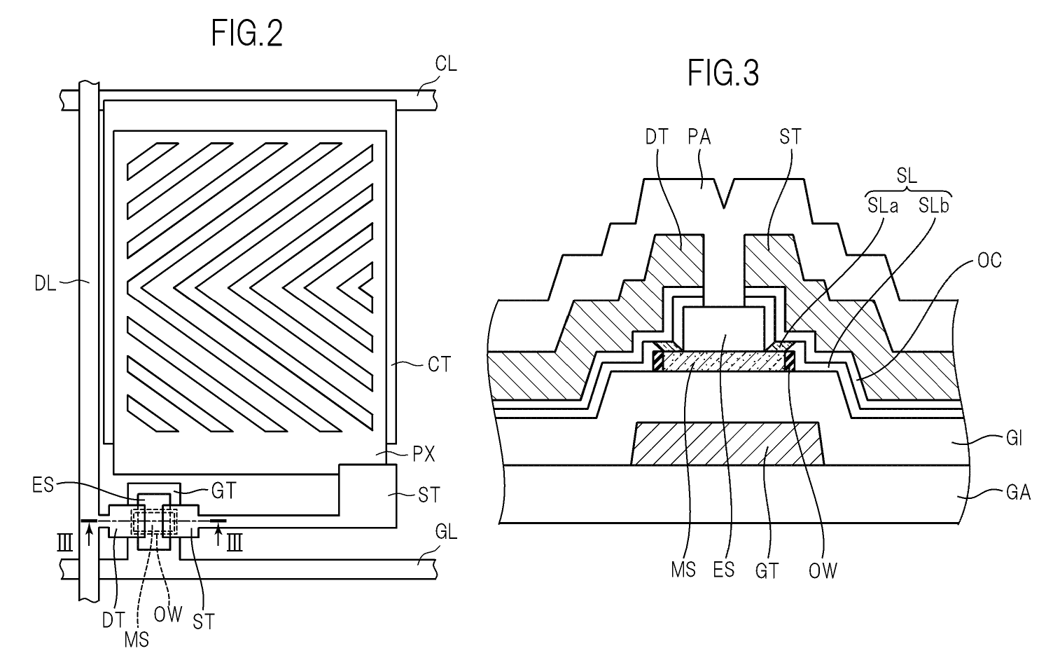

Further, FIG. 2 is an enlarged plan view of one pixel region on the thin film transistor substrate B1. As shown in FIG. 2, at a corner portion of the pixel region which is defined by the scanning signal lines GL and the video signal lines DL, the thin film transistor having the MIS (Metal-Insulator-Semiconductor) structure is formed. A gate electrode GT of the thin film transistor is connected to the scanning signal line GL, and a drain electrode DT of the thin film transistor is connected to the video signal line DL. A pixel electrode PX and a counter electrode CT which form a pair are formed in each pixel region, the pixel electrode PX is connected to a source electrode ST of the thin film transistor, and the counter electrode CT is connected to the common signal line CL.

In the above-mentioned constitution, a reference voltage is applied to the counter electrode CT of each pixel via the common signal line CL and a gate voltage is applied to the scanning signal line GL so that a row of pixels is selected. Further, at such timing of selection, a video signal is supplied to each video signal line DL so that a voltage of the video signal is applied to the pixel electrode PX of each pixel. Due to such an operation, a lateral electric field having field strength corresponding to the potential difference between the pixel electrode PX and the counter electrode CT is generated, and the alignment of liquid crystal molecules is determined corresponding to the field strength of the lateral electric field.

Next, the thin film transistor according to this embodiment is explained in detail. FIG. 3 is a view showing a cross section of the thin film transistor taken along a line in FIG. 2. As shown in FIG. 3, in the thin film transistor of this embodiment, a first semiconductor layer MS is formed over the gate electrode GT by way of a gate insulation layer GI. The first semiconductor layer MS forms a channel layer for controlling an electric current which flows between the drain electrode DT and the source electrode ST corresponding to a voltage applied to the gate electrode GT. The first semiconductor layer MS of this embodiment is made of microcrystalline silicon (μc-Si). Further, an insulation film ES which functions as an etching stopper is formed over the first semiconductor layer MS. The source electrode ST and the drain electrode DT are formed over the first semiconductor layer MS in a state where the source electrode ST and the drain electrode DT overlap a portion of the insulation film ES.

A source-electrode-side end portion and a drain-electrode-side end portion of the first semiconductor layer MS are exposed from the insulation film ES. Further, a second semiconductor layer SL and a third semiconductor layer OC are interposed between the source-electrode-side end portion and the source electrode ST and between the drain-electrode-side end portion and the drain electrode DT.

Particularly, the second semiconductor layer SL is, by setting a film forming condition described later, formed of a first portion SLa which is formed in a crystallized state by being brought into contact with the first semiconductor layer MS and a second portion SLb which has lower crystallinity than the first portion SLa. The first portion SLa is formed due to the growth of crystal from the first semiconductor layer MS at the time of forming the second semiconductor layer SL. The first portion SLa is formed such that the crystal grows in an outwardly expanding manner while being away from the insulation film ES as the first portion SLa advances toward an upper side in FIG. 3. In this embodiment, the first portion SLa is formed in a state where the first portion SLa is brought into contact with an upper surface of the first semiconductor layer MS, and the second portion SLb is formed in a state where the second portion SLb is brought into contact with an upper surface of the gate insulation layer GI. The first portion SLa is made of microcrystalline silicon, and the second portion SLb is made of amorphous silicon.

The third semiconductor layer OC is a layer for establishing an ohmic contact between the source electrode ST and the second semiconductor layer SL and between the drain electrode DT and the second semiconductor layer SL. The third semiconductor layer OC is formed using amorphous silicon or microcrystalline silicon doped with an impurity such as phosphorous in high concentration. The second semiconductor layer SL and the third semiconductor layer OC are formed by etching using the source electrode ST and the drain electrode DT as masks and hence, these semiconductor layers SL, OC have the same pattern shape as the source electrode ST and the drain electrode DT as viewed in a plan view. The second semiconductor layer SL or the like is formed such that the second semiconductor layer SL or the like extends onto the first semiconductor layer MS from a side of the first semiconductor layer MS and covers a portion of the first semiconductor layer MS exposed from the insulation film ES.

In this embodiment, a side-wall oxide film OW is formed at respective side walls of the first semiconductor layer MS. The side-wall oxide film OW is formed due to oxidation of the side walls of the first semiconductor layer MS which is formed into an island shape.

As described above, in the thin film transistor of this embodiment, due to the provision of the second semiconductor layer SL, a distance between the drain electrode DT and the gate electrode GT and a distance between the source electrode ST and the gate electrode GT are increased. Due to such an increase of the distance, strength of an electric field applied between the drain electrode DT and the gate electrode GT when a negative gate voltage is increased is relaxed so that the generation of an OFF current is suppressed. Further, the first portion SLa which forms a main path of an electric current which flows between the source/drain electrode and the first semiconductor layer MS has higher electric conductivity than the second portion SLb and hence, at the first portion SLa, lowering of an ON current can be suppressed.

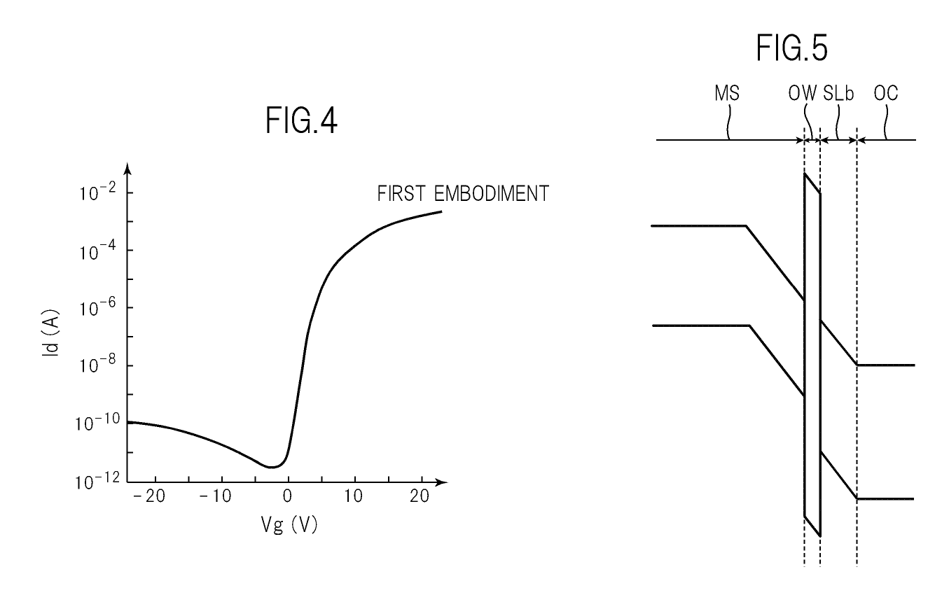

FIG. 4 is a graph showing a characteristic between a gate voltage and a drain current of the thin film transistor described above. As shown in FIG. 4, in the thin film transistor of this embodiment, an ON current is ensured and an OFF current is decreased.

FIG. 5 is a view showing the energy band structure on a side of the first semiconductor layer MS when a strong electric field is applied between the drain electrode DT and the gate electrode GT. As shown in FIG. 5, due to the presence of the side-wall oxide film OW having high insulation property and wide band gap, even when a strong electric field is applied to the side of the first semiconductor layer MS in a state where a negative gate voltage is increased, the generation of carriers caused by band-to-band tunneling can be suppressed.

Even when insulation property or a thickness of the side-wall oxide film OW is insufficient, the sideward growth of crystals of the first semiconductor layer MS is suppressed by the side-wall oxide films OW. Accordingly, on a side of the side-wall oxide film OW, the second portion SLb which has lower crystallinity than the first portion SLa formed over the first semiconductor layer MS is formed. The second portion SLb has a wider band gap than the first semiconductor layer MS and the first portion SLa and hence, the generation of carriers when a negative gate voltage is increased can be further suppressed. In view of the above, it is preferable to suppress the sideward growth of crystals by forming the side-wall oxide film OW on the side walls of the first semiconductor layer MS as described in this embodiment. Due to the suppression of the sideward growth of the crystals, an OFF current caused by a strong electric field which may be generated on the sides of the first semiconductor layer MS can be suppressed.

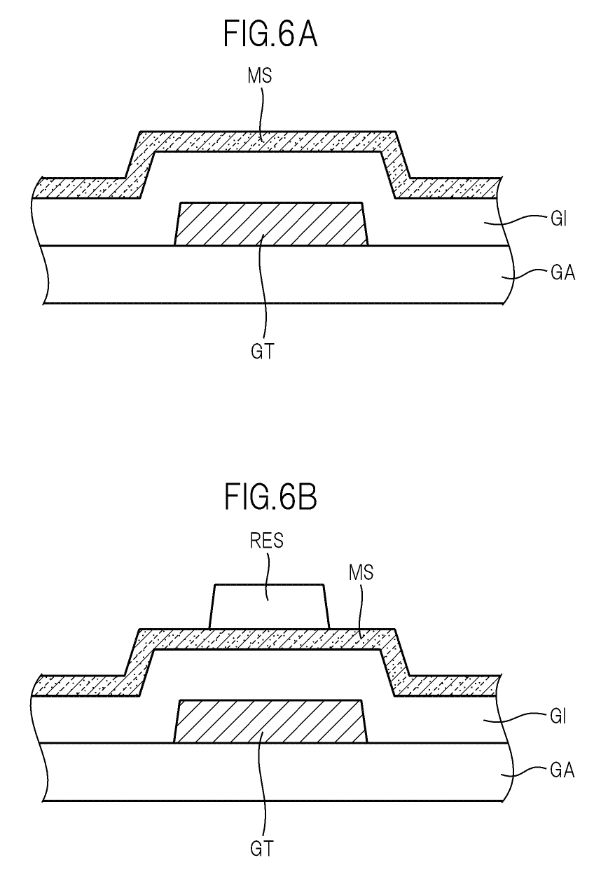

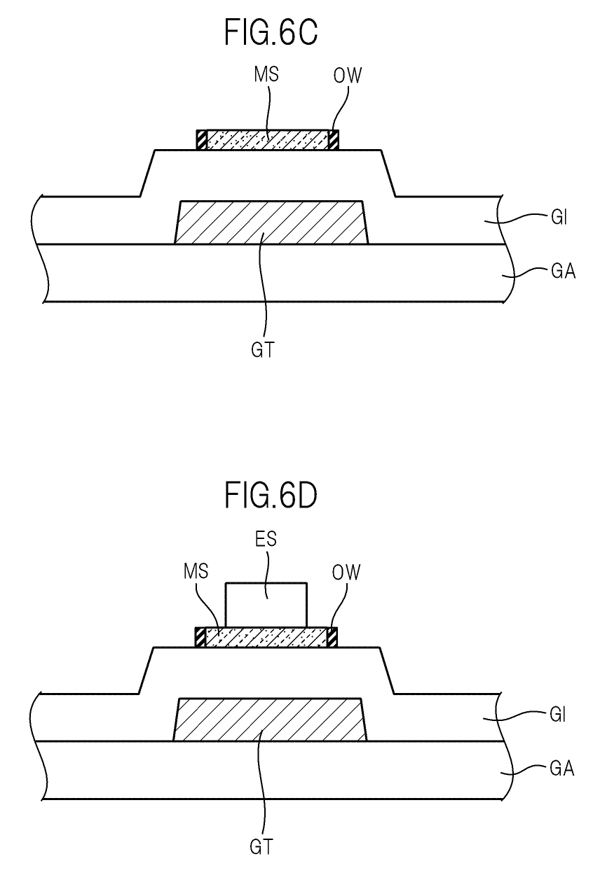

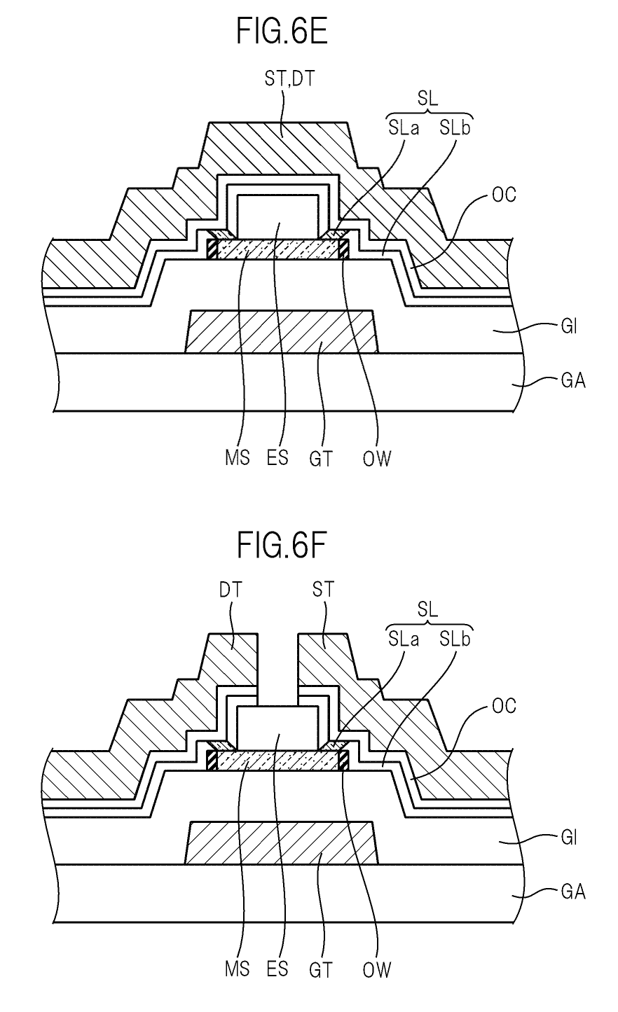

The structure of the thin film transistor which is formed over the thin film transistor substrate B1 according to this embodiment has been explained heretofore. A method of manufacturing the thin film transistor is explained in conjunction with FIG. 6A to FIG. 6F hereinafter.

Firstly, as shown in FIG. 6A, the gate electrode GT is formed over a transparent substrate GA such as a glass substrate and, then, the gate insulation layer GI and the first semiconductor layer MS are formed so as to cover the gate electrode GT.

The gate electrode GT is formed such that a film made of a conductive metal such as molybdenum, for example, is formed and the film is formed into a shape shown in FIG. 6A through a photolithography step and an etching step. The gate insulation layer GI is formed by depositing silicon dioxide, for example, by a CVD method. Then, in forming the first semiconductor layer MS of this embodiment, a film made of microcrystalline silicon is firstly directly formed over the gate insulation layer GI by a plasma CVD method.

Next, as shown in FIG. 6B, a resist RES is formed through a photolithography step. The first semiconductor layer MS is formed into an island shape by etching using the resist RES as a mask. FIG. 6C is a view showing the manner of forming the side-wall oxide film OW on the side walls of the first semiconductor layer MS which is formed into an island shape. The side-wall oxide films OW may be formed by oxidizing the side walls of the first semiconductor layer MS by ozone asking at the time of removing the resist RES or, for example, may be formed by applying ozone water treatment before the resist RES is removed.

Then, as shown in FIG. 6D, the insulation film ES which functions as an etching stopper is formed. The insulation film ES is formed such that a film made of silicon dioxide or the like is formed by a CVD method after the side-wall oxide film OW is formed, and the film is formed into a shape as shown in FIG. 6D through a photolithography step and an etching step. As shown in FIG. 6D or the like, the insulation film ES is arranged on the first semiconductor layer MS, and a source-electrode-side end portion and a drain-electrode-side end portion of the first semiconductor layer MS are exposed from the insulation film ES.

After the insulation film ES is formed, as shown in FIG. 6E, the second semiconductor layer SL, the third semiconductor layer OC, and a material film for forming the source/drain electrodes ST, DT are sequentially formed.

Firstly, the second semiconductor layer SL is formed by a plasma CVD method. As a raw material gas, for example, a hydrogenated gas of silicon such as SiH₄ (mono-silane) or Si₂H₆ (disilane), or a halogenated gas of silicon such as SiF₄ (silane fluoride) is used. A carrier gas such as H₂, He or Ar is supplied simultaneously with the supply of the raw material gas. In this embodiment, as described above, the microcrystal layer grows at a portion of the second semiconductor layer SL where a background is formed of a microcrystal layer, and a microcrystal layer having insufficient crystallinity or an amorphous layer is formed at a portion of the second semiconductor layer SL where the background is formed of an insulation layer. In forming the second semiconductor layer SL as described above, it is sufficient to set a flow rate of mono-silane which is a raw material gas smaller than a flow rate of hydrogen which is a carrier gas. It is preferable to set a flow rate between mono-silane and hydrogen to 1/100 or less, for example. Further, although a room temperature or more can be used as a film forming temperature, it is preferable to set the film forming temperature to 200° C. or more and 400° C. or less. A film forming pressure may be set to 2 torr or less, for example. As a plasma CVD device, it is sufficient to use a CVD device having the parallel-flat-plate-type electrode structure.

Thereafter, the third semiconductor layer OC is formed using amorphous silicon in a state where the third semiconductor layer OC is brought into contact with the second semiconductor layer SL, and the source/drain electrodes ST, DT are formed in a state where the source/drain electrodes ST, DT are brought into contact with an upper surface of the third semiconductor layer OC. The third semiconductor layer OC is formed such that the third semiconductor layer OC is doped with an impurity at the time of forming an amorphous silicon film by a CVD method. The source/drain electrodes ST, DT are formed using aluminum or an alloy containing aluminum by a sputtering method. The third semiconductor layer OC maybe formed by implanting an impurity into an amorphous silicon layer after the amorphous silicon layer is formed. Further, the third semiconductor layer OC maybe formed of a microcrystalline silicon layer.

After forming the material film for forming the source/drain electrodes ST, DT, as shown in FIG. 6F, the second semiconductor layer SL, the third semiconductor layer OC, the source electrode ST and the drain electrode DT are formed into predetermines shapes respectively. Such shape forming is performed through a photolithography step and an etching step, wherein the third semiconductor layer OC and the second semiconductor layer SL are laminated with the same pattern shape as the drain electrode DT and the like. Finally, a passivation film PAmade of silicon nitride is formed by a plasma CVD method thus forming the thin film transistor shown in FIG. 3.

In this embodiment, the first semiconductor layer MS is formed of a microcrystalline silicon layer which is directly formed as a film by a CVD method. However, the first semiconductor layer MS may be formed of a microcrystalline silicon layer which is crystallized by applying heat treatment to an amorphous silicon layer formed by a CVD method. Further, the first semiconductor layer MS may be formed of a polycrystalline silicon layer which is formed by crystallizing an amorphous silicon layer formed by a CVD method using an excimer laser beam or an RTA (Rapid Thermal Anneal) method. That is, it is sufficient that the first semiconductor layer MS is formed of a semiconductor layer having crystallinity. A grain size of microcrystalline silicon of this embodiment falls within a range of 10 nm or more and approximately 100 nm or less, and the grain size can be confirmed by reflection electron beam diffraction, Raman spectroscopy or the like.

Here, although the display device of this embodiment is the IPS-type liquid crystal display device, the display device may be a liquid crystal display device which adopts other drive methods such as a VA (Vertically Aligned) method or a TN (Twisted Nematic) method, or maybe other display devices such as an organic EL display device.

### Second Embodiment

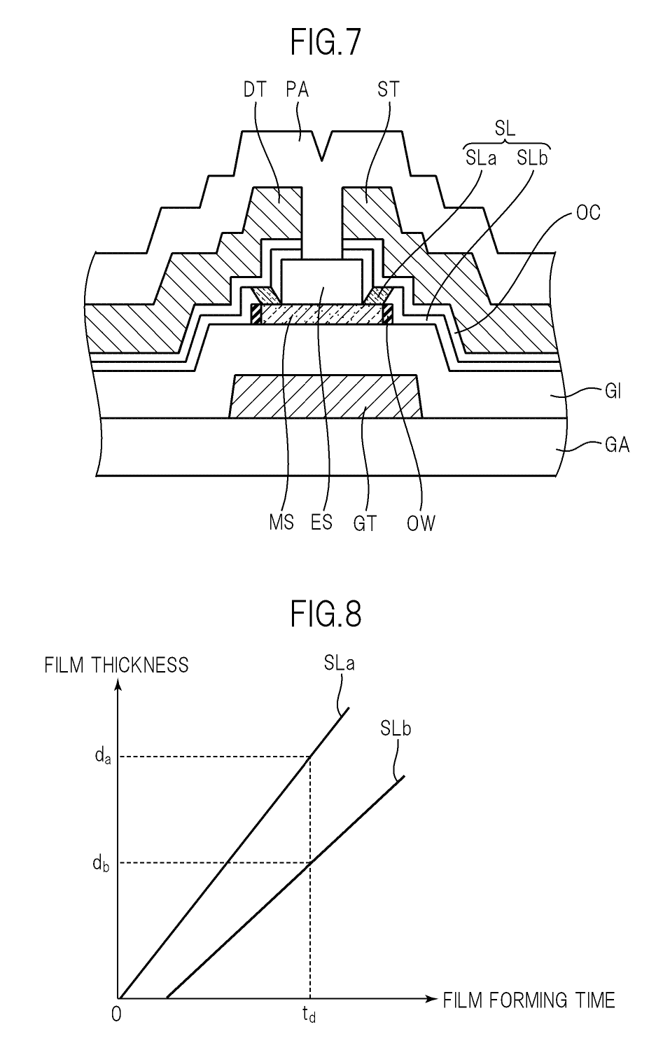

Next, a display device according to a second embodiment of the present invention is explained. FIG. 7 is a view showing a cross section of a thin film transistor of the display device according to the second embodiment, and is a cross-sectional view corresponding to a cross section taken along the line in FIG. 2 which is the enlarged plan view.

In the thin film transistor of the second embodiment, a first portion SLa which is formed over a first semiconductor layer MS and a second portion SLb which is formed over a gate insulation layer GI are formed with different thicknesses, and the thickness of the second portion SLb is set smaller than the thickness of the first portion SLa. Due to such a constitution, while maintaining a distance between a gate electrode GT and a drain electrode DT by the first portion SLa, the generation of carriers caused by the irradiation of light from a glass substrate GA side can be more efficiently suppressed compared to the case of the first embodiment. The thin film transistor of the second embodiment has the substantially same constitution as the thin film transistor of the first embodiment with respect to parts except for such a point and hence, the explanation of these parts is omitted.

Next, the explanation is made with respect to the formation of a second semiconductor layer SL of the second embodiment. In the second embodiment, although a plasma CVD method or a thermal CVD method is used, compared to the film forming condition applied to the first embodiment, a raw material gas may be more diluted with respect to a carrier gas or a film forming pressure may be further lowered. By setting the film forming condition in such a manner, an amorphous component can be easily etched by a carrier gas and hence, it is possible to facilitate the growth of a crystalline film containing a small amount of amorphous component on the first semiconductor layer MS.

FIG. 8 is a graph showing the relationship between a film forming time and a film thickness of the second semiconductor layer SL under the film forming condition applied to the second embodiment. As shown in FIG. 8, at a film forming time t_{d}, a film thickness of the first portion SLa is dₐ and a film thickness of the second portion SLb is d_{b}. Accordingly, it is possible to make the film thickness of the first portion SLa and the film thickness of the second portion SLb of the second semiconductor layer SL differ from each other.

### Third Embodiment

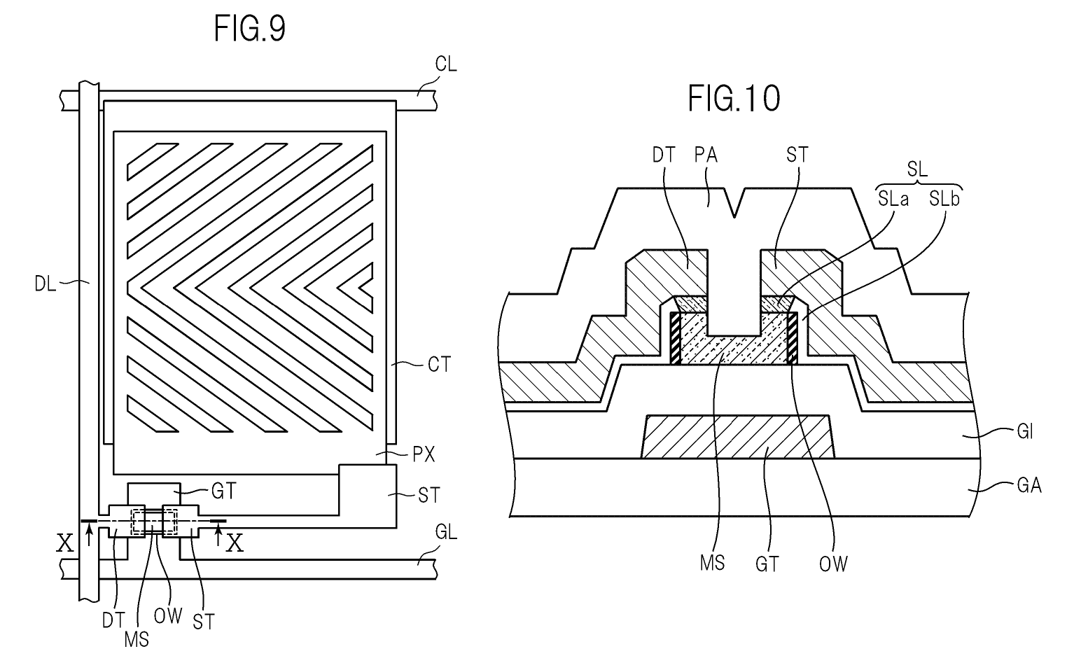

Next, a display device according to a third embodiment of the present invention is explained. FIG. 9 is an enlarged plan view of one pixel region of a thin film transistor substrate B1 of the third embodiment, and FIG. 10 is a view showing a cross section of the thin film transistor substrate B1 taken along a line X-X in FIG. 9.

As shown in FIG. 10, the thin film transistor of the third embodiment is a channel-etch-type thin film transistor. Further, in the third embodiment, a third semiconductor layer OC is not formed, and a second semiconductor layer SL having a first portion SLa and a second portion SLb is doped with an impurity. The thin film transistor of the third embodiment has the substantially same constitution as the thin film transistor of the first embodiment with respect to parts except for such a point and hence, the explanation of these parts is omitted.

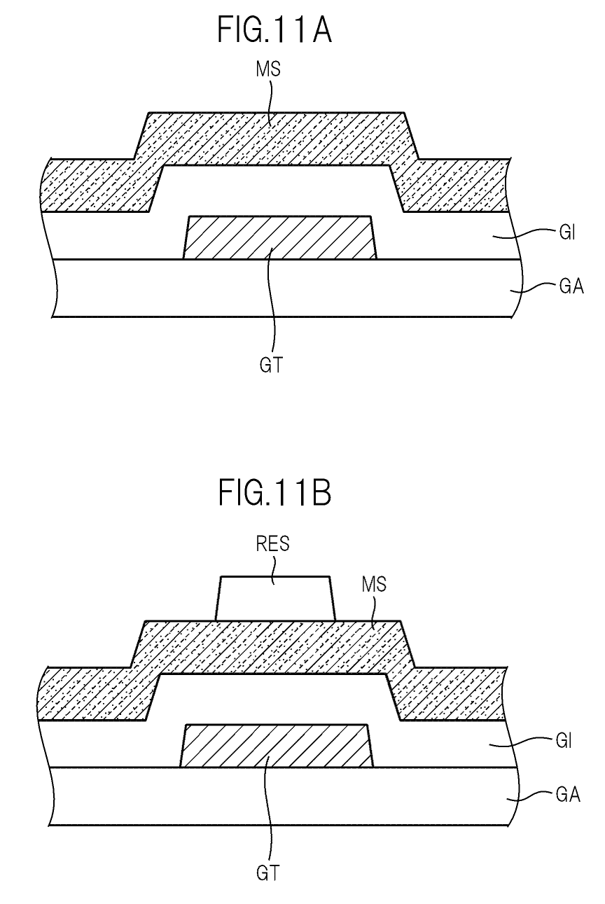

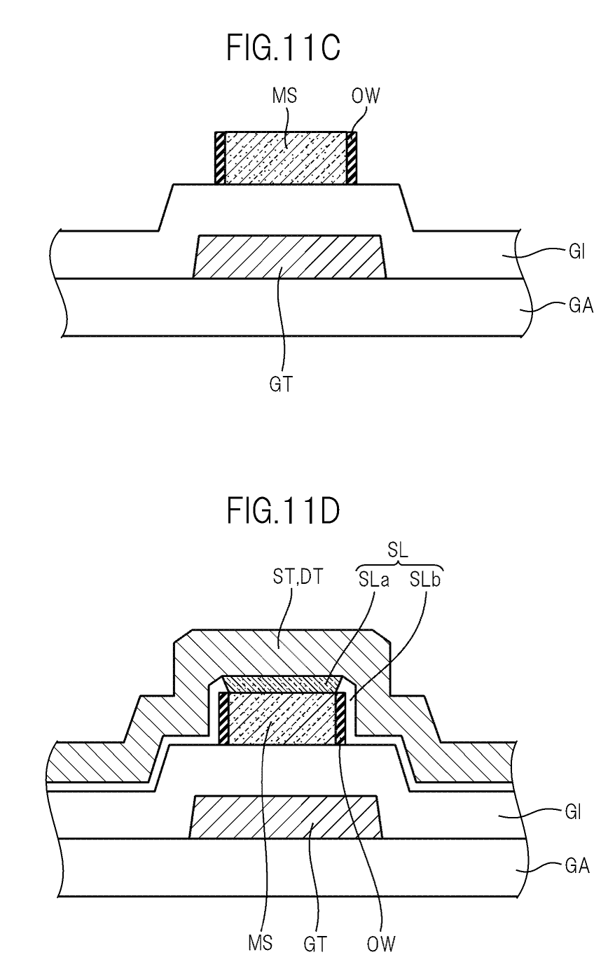

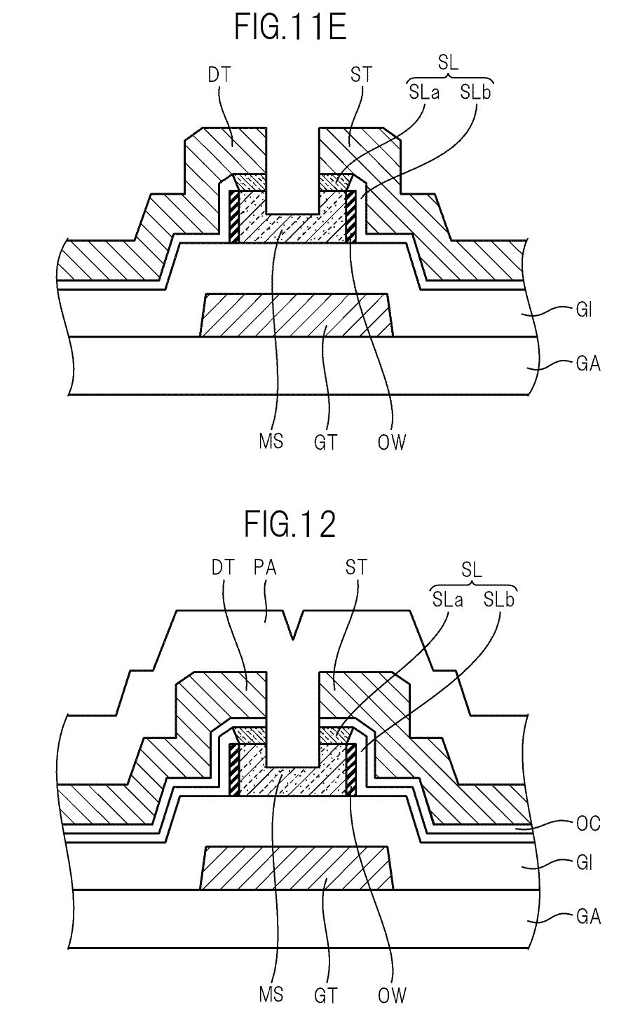

FIG. 11A to FIG. 11E are views showing the manner of manufacturing the thin film transistor of the third embodiment. Firstly, as shown in FIG. 11A, a gate electrode GT is formed over a transparent substrate GA such as a glass substrate, and a gate insulation layer GI and a first semiconductor layer MS are formed so as to cover the gate electrode GT. In this embodiment, the thin film transistor is a channel-etching-type thin film transistor and hence, the first semiconductor layer MS is formed with a thickness larger than a film thickness of the first semiconductor layer MS of the first embodiment.

Next, as shown in FIG. 11B, a resist RES is formed through a photolithography step. The first semiconductor layer MS is formed into an island shape using the resist RES. Then, as shown in FIG. 11C, a side-wall oxide film OW is formed at side walls of the first semiconductor layer MS which is formed into an island shape.

Further, as shown in FIG. 11D, the second semiconductor layer SL and a material film for forming the source/drain electrodes ST, DT are sequentially formed. At the time of forming the second semiconductor layer SL, in the same manner as the case of the first embodiment, a raw material gas and a carrier gas are supplied to the inside of a film forming device and, at the same time, as a doping gas, a phosphine (PH₃) gas or a phosphine gas diluted with hydrogen is supplied to the inside of the film forming device.

The second semiconductor layer SL is formed as described above and hence, the second semiconductor layer SL is formed of a semiconductor layer doped with an impurity, and an ohmic contact is established between the second semiconductor layer SL and the source/drain electrodes ST, DT. Further, the second semiconductor layer SL has a first portion SLa which is formed due to the growth of crystal at a portion thereof which is brought into contact with an upper surface of the first semiconductor layer MS, and also has a second portion SLb which has lower crystallinity than the first portion SLa at a portion thereof which is brought into contact with the gate insulation layer GI and the side-wall oxide film OW.

After forming the material film for forming the source/drain electrodes ST, DT, as shown in FIG. 11E, the source electrode ST, the drain electrode DT and the second semiconductor layer SL are formed into predetermined shapes respectively, and a portion of the first semiconductor layer MS is eroded by etching. Thereafter, a passivation film PA is formed by a plasma CVD method using silicon nitride thus forming the thin film transistor shown in FIG. 10.

### Fourth Embodiment

Next, a display device according to a fourth embodiment of the present invention is explained. FIG. 12 is a view showing a cross section of a thin film transistor of the display device according to the fourth embodiment, and is a cross-sectional view corresponding to the cross section of the thin film transistor taken along a line X-X in FIG. 9 which is the enlarged plan view of the third embodiment.

The thin film transistor of the fourth embodiment is, as shown in FIG. 12, a channel-etching-type thin film transistor in the same manner as the third embodiment. However, the fourth embodiment differs from the third embodiment with respect to a point that a third semiconductor layer OC doped with an impurity at high concentration is formed between a second semiconductor layer SL and source/drain electrodes ST, DT, and a point that the second semiconductor layer SL is not doped with an impurity. The thin film transistor of the fourth embodiment has the substantially same constitution as the thin film transistor of the third embodiment with respect to parts except for these points and hence, the explanation of these parts is omitted.

In the thin film transistor of the fourth embodiment, different from the thin film transistor of the third embodiment, the third semiconductor layer OC can be formed separately from the second semiconductor layer SL and hence, a distance between the gate electrode GT and the drain electrode DT can be increased whereby the generation of an OFF current can be suppressed more compared to the case described in the third embodiment. Further, in the thin film transistor of the fourth embodiment, a semiconductor layer doped with an impurity is not brought into contact with a side-wall oxide film OW and hence, the generation of an OFF current can be suppressed more compared to the case described in the third embodiment.

### Fifth Embodiment

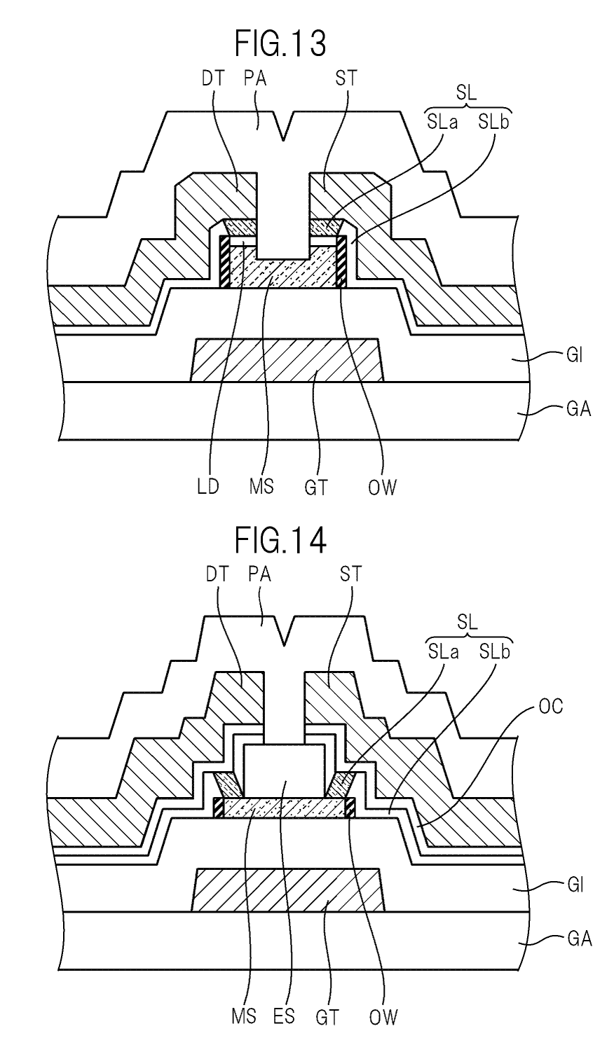

Next, a display device according to a fifth embodiment of the present invention is explained. FIG. 13 is a view showing a cross section of a thin film transistor of the display device according to the fifth embodiment, and is a cross-sectional view corresponding to the cross section of the thin film transistor taken along a line X-X in FIG. 9 which is an enlarged plan view of the third embodiment.

As shown in FIG. 13, the thin film transistor of the fifth embodiment is a channel-etching-type thin film transistor in the same manner as the third embodiment. However, the fifth embodiment differs from the third embodiment with respect to a point that a first semiconductor layer MS is formed such that the first semiconductor layer MS includes low-concentration impurity regions LD. The thin film transistor of the fifth embodiment has the substantially same constitution as the thin film transistor of the third embodiment with respect to parts except for these points and hence, the explanation of these parts is omitted.

The low-concentration impurity regions LD are formed by being doped with an impurity at the time of forming an upper surface portion of the first semiconductor layer MS by a plasma CVD method. The low-concentration impurity region LD is formed with lower impurity concentration than a second semiconductor layer SL which is formed by being doped with an impurity.

### Sixth Embodiment

Next, a display device according to a sixth embodiment of the present invention is explained. FIG. 14 is a view showing a cross section of a thin film transistor of the display device according to the sixth embodiment, and is a cross-sectional view corresponding to the cross section of the thin film transistor taken along the line III-III in FIG. 2 which is the enlarged plan view.

The thin film transistor of the sixth embodiment is, as shown in FIG. 14, a channel-stopper-type thin film transistor in the same manner as the second embodiment. However, the thin film transistor of this embodiment differs from the thin film transistor of the second embodiment with respect to a point that a second semiconductor layer SL is formed containing germanium (Ge). The second semiconductor layer SL contains germanium and hence, the difference in thickness between a first portion SLa and a second portion SLb which are formed at the time of forming the second semiconductor layer SL can be increased compared to the case described in the second embodiment. The thin film transistor of the sixth embodiment has the substantially same constitution as the thin film transistor of the second embodiment with respect to parts except for this point and hence, the explanation of these parts is omitted.

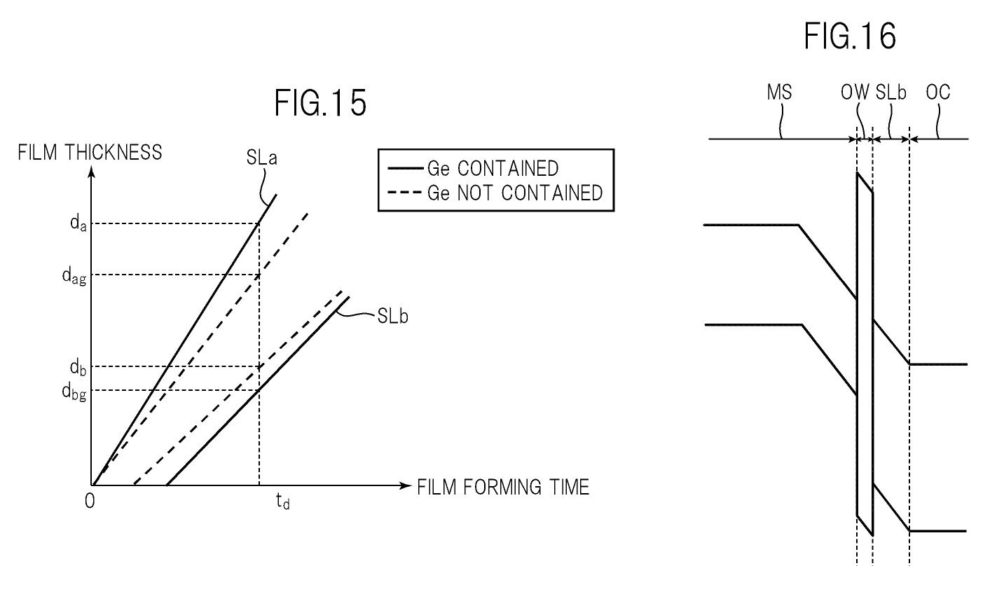

FIG. 15 is a graph showing the relationship between a film forming time and a film thickness under a film forming condition used in the sixth embodiment. In FIG. 15, the relationship between the film forming time and the film thickness with respect to the first portion SLa and the second portion SLb in the sixth embodiment is indicated by a solid line, and the relationship between the film forming time and the film thickness with respect to the first portion SLa and the second portion SLb in the second embodiment is indicated by a broken line.

In the sixth embodiment, when the second semiconductor layer SL is formed by a plasma CVD method, a raw material gas containing germanium is further supplied together with the raw material gas and the carrier gas explained in conjunction with the first embodiment. Accordingly, desorption of hydrogen atoms which terminate a growth site on a film surface is accelerated and hence, a film forming speed of a portion of the second semiconductor layer SL which is brought into contact with the first semiconductor layer MS can be increased. On the other hand, at a portion of the second semiconductor layer SL which is formed over an insulation layer such as a silicon oxide film, germanium is bonded to oxygen atoms which the silicon oxide film contains and a bonded substance is desorbed in a gas phase space as GeO and hence, a film forming time of the second semiconductor layer SL is delayed compared to the formation of the second semiconductor layer SL on the first semiconductor layer MS.

As shown in FIG. 15, when the second semiconductor layer SL contains germanium, a film thickness ratio (d_{ag}/d_{bg}) within the same film forming time (t_{d}) can be increased compared to the case described in the second embodiment. Accordingly, the generation of carriers caused by the irradiation of light from a glass substrate GA side can be further suppressed.

### Seventh Embodiment

Next, a display device according to a seventh embodiment of the present invention is explained. A thin film transistor of the display device according to the seventh embodiment has the substantially same constitution as the thin film transistor of the first embodiment except for a point that a second semiconductor layer SL contains carbon (C).

FIG. 16 is a view showing the energy band structure on a side of a first semiconductor layer MS when a strong electric field is applied to a drain electrode DT and a gate electrode ST in the thin film transistor of the seventh embodiment. As shown in FIG. 16, a second portion SLb contains carbon and hence, an energy band gap is increased. Accordingly, even when a strong electric field is applied to the side of the first semiconductor layer MS in a state where a negative gate voltage is increased, the generation of carriers caused by band-to-band tunneling can be suppressed.

The second semiconductor layer SL may be formed by making use of a plasma CVD method or a thermal CVD method, for example, wherein a hydrocarbon gas such as CH SiH₃ (mono methyl silane) or methane (CH₄) or a diluted gas of such a gas is simultaneously supplied as a raw material gas of carbon, for example, in addition to respective conditions applied to the first embodiment.

Although the respective embodiments of the present invention have been explained heretofore, the present invention is not limited to the above-mentioned embodiments and various modifications are conceivable. For example, the constitutions explained in conjunction with the respective embodiments may be replaced with the constitutions which are substantially equal to the constitutions of the respective embodiments, the constitutions which can acquire the same advantageous effects as the constitutions of the respective embodiments, or the constitutions which can achieve the same object as the constitutions of the respective embodiments.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a gate electrode;
a first semiconductor layer in a crystallized state which is formed over the gate electrode;
a source electrode and a drain electrode which are formed over the first semiconductor layer; and
a second semiconductor layer which extends from a side of the first semiconductor layer and is interposed between one of the source electrode and the drain electrode and the first semiconductor layer, wherein
the second semiconductor layer includes a first portion which is formed in a crystallized state and brought into contact with the first semiconductor layer, and a second portion which has lower crystallinity than the first portion.

2. The display device according to claim 1, wherein an insulation layer is formed between the gate electrode and the first semiconductor layer, the first portion of the second semiconductor layer is formed over the first semiconductor layer, and the second portion of the second semiconductor layer is formed over the insulation layer.

3. The display device according to claim 1, wherein the display device further comprises a side-wall oxide film which is formed at a side wall of the first semiconductor layer.

4. The display device according to claim 2, wherein the first portion of the second semiconductor layer is formed thicker than the second portion of the second semiconductor layer.

5. The display device according to claim 1, wherein the display device further comprises a third semiconductor layer which is formed over the second semiconductor layer by being doped with an impurity.

6. The display device according to claim 1, wherein the second semiconductor layer is doped with an impurity.

7. The display device according to claim 6, wherein an upper surface of the first semiconductor layer is doped with an impurity, and the second semiconductor layer has the higher impurity concentration than the upper surface of the first semiconductor layer.

8. The display device according to claim 1, wherein the second semiconductor layer contains germanium.

9. The display device according to claim 1, wherein the second semiconductor layer contains carbon.

10. A method of manufacturing a display device which includes: a gate electrode; a first semiconductor layer in a crystallized state which is formed over the gate electrode; a source electrode and a drain electrode which are formed over the first semiconductor layer; and a second semiconductor layer which extends from a side of the first semiconductor layer and is interposed between one of the source electrode and the drain electrode and the first semiconductor layer, the method comprising a step of:
forming the second semiconductor layer as a film by setting a ratio of a flow rate of a raw material gas with respect to a flow rate of a carrier gas to 1/10 or less thus forming a first portion which is crystallized and brought into contact with the first semiconductor layer, and a second portion having lower crystallinity than the first portion in the second semiconductor layer.
